(19) United States
(12) Patent Application Publication
(10) Pub. No.: US 2013/0314886 A1
(43) Pub. Date: Nov. 28, 2013

(54) WIRING BOARD AND MOUNTING STRUCTURE

(71) Applicant: SHINKO ELECTRIC INDUSTRIES CO., LTD., Nagano (JP)

(72) Inventors: Kazuhiro KOBAYASHI, Nagano (JP); Junichi Nakamura, Nagano (JP)

(73) Assignee: SHINKO ELECTRIC INDUSTRIES CO., LTD., Nagano (JP)

(21) Appl. No.: 13/892,402

(22) Filed: May 13, 2013

(30) Foreign Application Priority Data
May 24, 2012 (JP) 2012-119046

(51) Int. Cl. H05K 1/11

(52) U.S. Cl. CPC H05K 1/112
USPC 361/767; 174/266

(57) ABSTRACT

A wiring board includes an insulating layer; a connection part provided on a surface of the insulating layer, the connection part including a first plating layer including a flat surface and a curved surface continuous with the flat surface, wherein the flat surface and the curved surface are exposed on the insulating layer, and an end portion of the curved surface is in contact with the surface of the insulating layer; and a second plating layer formed on an interior surface of the first plating layer so as to be coated with the first plating layer; and a via formed in the insulating layer so as to be connected to the second plating layer.

### CROSS-REFERENCE TO RELATED APPLICATION

This application is based upon and claims the benefit of priority of the prior Japanese Patent Application No. 2012-119046, filed on May 24, 2012, the entire contents of which are incorporated herein by reference.

### FIELD

A certain aspect of the embodiments discussed herein is related to a wiring board and a mounting structure.

### BACKGROUND

There is a conventional method of manufacturing a wiring board that includes the process of forming a laminate of wiring layers and insulating layers on a support and the process of removing the support. According to this method of manufacturing a wiring board, the process of forming curved-surface depressions on the surface of the support at positions corresponding to positions where curved-surface projecting connection parts are to be formed is executed before the process of forming the laminate. (See, for example, Japanese Laid-Open Patent Application No. 2009-064973.)

### SUMMARY

According to an aspect of the invention, a wiring board includes an insulating layer; a connection part provided on a surface of the insulating layer, the connection part including a first plating layer including a flat surface and a curved surface continuous with the flat surface, wherein the flat surface and the curved surface are exposed on the insulating layer, and an end portion of the curved surface is in contact with the surface of the insulating layer; and a second plating layer formed on an interior surface of the first plating layer so as to be coated with the first plating layer; and a via formed in the insulating layer so as to be connected to the second plating layer.

According to an aspect of the invention, a mounting structure includes the wiring board as set forth above; and a semiconductor chip mounted on the wiring board, the semiconductor chip including a pad connected via solder to the flat surface and the curved surface of the first plating layer of the wiring board.

The object and advantages of the invention will be realized and attained by means of the elements and combinations particularly pointed out in the claims.

It is to be understood that both the foregoing general description and the following detailed description are exemplary and explanatory and not restrictive of the invention.

### BRIEF DESCRIPTION OF DRAWINGS

FIG. 1 is a cross-sectional view of part of a wiring board of a comparative example;

FIGS. 2A through 2C are diagrams illustrating a method of manufacturing a bump of the wiring board of the comparative example;

FIG. 3 is a cross-sectional view of part of an IC package in which an IC chip is mounted on the wiring board of the comparative example by flip chip;

FIG. 4 is a cross-sectional view of part of a wiring board according to an embodiment;

FIG. 5 is a diagram illustrating a cross-sectional structure of a cladding material used to manufacture a bump of the wiring board according to an embodiment;

FIGS. 6A through 6J are diagrams illustrating a process for manufacturing the wiring board according to an embodiment;

FIG. 7 is a cross-sectional view of part of an IC package that includes the wiring board according to an embodiment;

FIG. 8 is a cross-sectional view of an IC package according to an embodiment; and

FIGS. 9A through 9C are diagrams illustrating variations of the wiring board according to an embodiment.

### DESCRIPTION OF EMBODIMENTS

In the process of manufacturing a wiring board for mounting an electronic device having multiple pads, such as an IC (integrated circuit) chip, multiple connection parts as those described above with reference to Japanese Laid-open Patent Publication No. 2009-064973 are formed. The multiple connection parts are arranged in a plane and are used as, for example, bumps.

Therefore, in order to form multiple connection parts by the above-described method of manufacturing a wiring board, multiple curved-surface depressions are so formed on the support as to be arranged in a plane. The curved-surface depressions are formed by etching the surface of the support.

However, when multiple curved-surface depressions are formed in a plane, the curved-surface depressions vary in depth. As a result, multiple connection parts, which are formed using the curved-surface depressions, vary in height. The curved-surface depressions are caused to vary in depth by, for example, variations in the amount of an etchant.

In the case of mounting an IC chip on a wiring board having such connection parts by flip chip, the connection parts of the wiring board and the pads of the IC chip are soldered.

However, because the connection parts of the wiring board vary in height, the connection parts of the wiring board may be prevented from coming into good contact with the corresponding pads of the IC chip. If the connection parts of the wiring board are prevented from coming into good contact with the corresponding pads of the IC chip, this reduces the reliability of the wiring board.

According to an aspect of the invention, a highly reliable wiring board and mounting structure are provided.

Preferred embodiments of the present invention will be explained with reference to accompanying drawings.

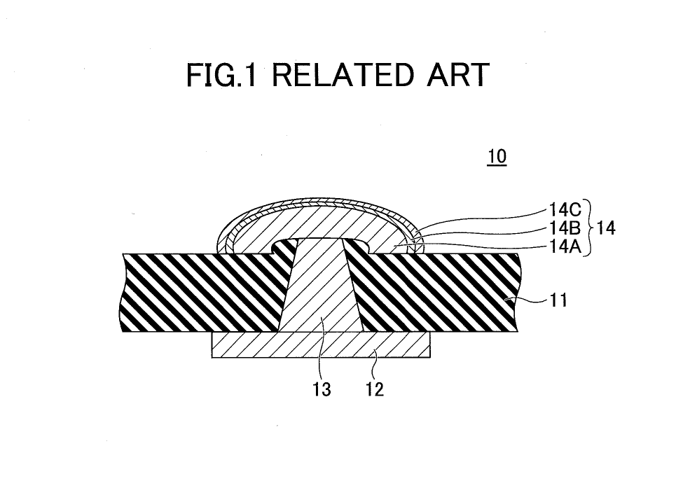

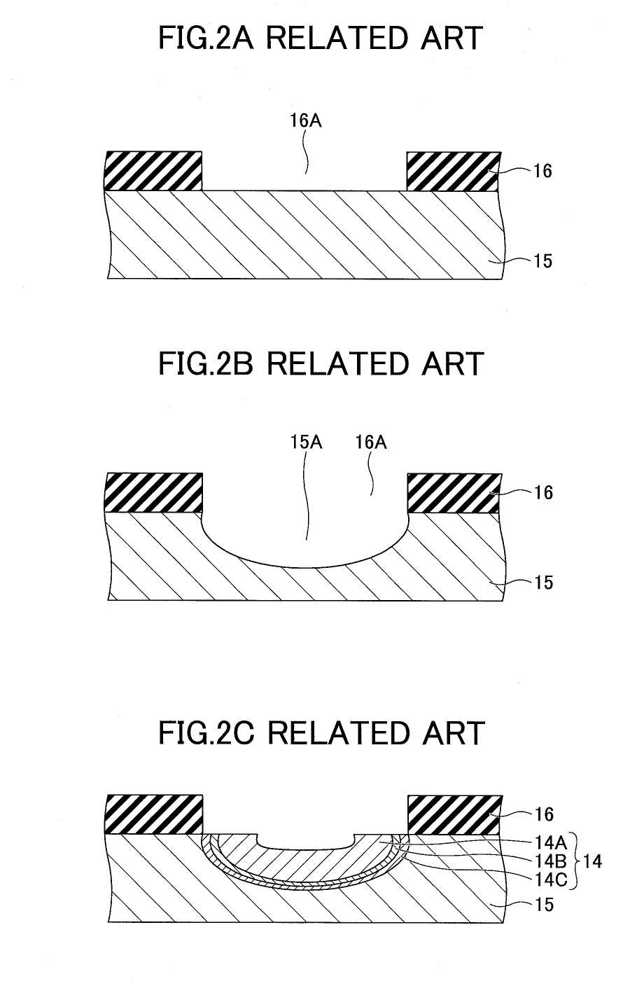

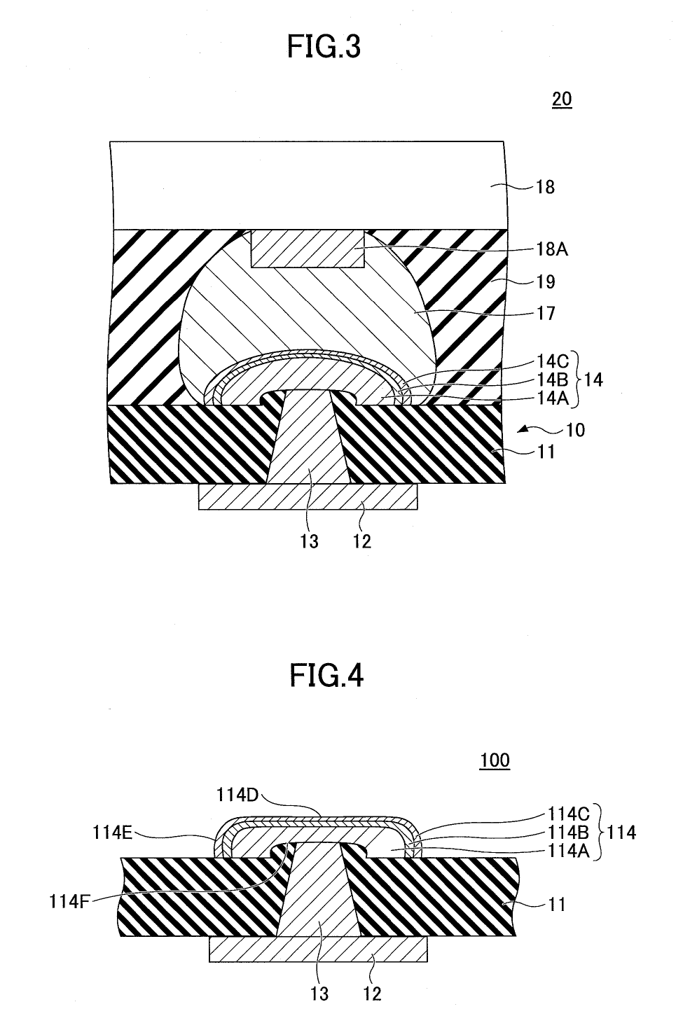

Before describing embodiments to which a wiring board, a mounting structure, and a method of manufacturing a wiring board are applied, a description is given, with reference to FIG. 1, FIGS. 2A through 2C, and FIG. 3, of a connection structure and an electronic device according to a comparative example.

### Comparative Example

FIG. 1 is a cross-sectional view of part of a wiring board of the comparative example. In FIG. 1, one pad, one via, and one interconnect are illustrated. FIGS. 2A through 2C are diagrams illustrating a process for manufacturing a pad of the comparative example. FIG. 3 is a cross-sectional view of part of an IC package in which an IC chip is mounted on the wiring board of the comparative example by flip chip.

Referring to FIG. 1, a wiring board 10 of the comparative example includes an insulating layer 11, a wiring layer 12, a via 13, and a bump 14.

The insulating layer 11 is, for example, one of multiple insulating layers included in a build-up board. The build-up board is manufactured by stacking wiring layers and insulating layers (not graphically illustrated) on the insulating layer 11 of the wiring board 10 illustrated in FIG. 1 (in the downward direction in FIG. 1) .

The lamination of such a build-up board is upside down relative to the state illustrated in FIG. 1. Examples of the insulating layer 11 include an insulating layer of an epoxy resin.

The wiring layer 12 is, for example, one of wiring layers included in a build-up board. The wiring layer is patterned as desired to connect to an IC chip or the like, and is connected to the via 13 formed inside the insulating layer 11 in its thickness direction. The wiring layer 12 may be formed using, for example, a semi-additive process. For example, copper foil may be used as the wiring layer 12.

The via 13 is, for example, a via included in a build-up board and is formed inside a via hole formed through the insulating layer 11 in its thickness direction. Such a via hole may be formed by, for example, laser processing.

The via 13 is formed by, for example, filling a via hole with a copper film by plating. In FIG. 1, the via 13 has its lower end connected to the wiring layer 12 and has its upper end connected to the bump 14.

The bump 14 is connected to the upper end of the via 13 on a surface of the insulating layer 11. The bump 14 includes a copper layer 14A, a nickel layer 14B, and a gold layer 14C. The bump 14 has a surface that is curved substantially hemispherically. The bump 14 is shaped like a thinly flattened hemisphere. Further, a surface of the copper layer 14A, which surface is in contact with the surface of the insulating layer 11, includes a part that is connected to the via 13. The part of the surface of the copper layer 14A is depressed relative to the surface of the insulating layer 11, so that the depression is filled with the insulating layer 11.

Here, a description is given, with reference to FIGS. 2A through 2C, of a method of manufacturing the bump 14 of the wiring board 10 of the comparative example.

First, as illustrated in FIG. 2A, a resist 16 is formed on a surface of copper foil 15. The resist 16 includes an opening 16A that corresponds to the position and size of the bump 14 to be formed later. The opening 16A is circular in a plan view. Practically, multiple openings 16A are formed in correspondence to the number of the bumps 14.

Next, the copper foil 15 is selectively removed by wet etching, so that a hole 15A is formed as illustrated in FIG. 2B. The hole 15A, which is formed by selectively removing part of the copper foil 15 by wet etching, has a concave shape that is substantially hemispherically curved because of the isotropy of the etching. The hole 15A is deepest in the plan-view center and becomes shallower toward the edge. The depth thus differs partly because the amount of an etchant ejected by an etching apparatus is greater in the center than on the edge of the hole 15A.

Therefore, the depth of the hole 15A is not uniform, and varies depending on a planar position. The hole 15A is circular in a plan view. The hole 15A is shaped like a thinly flattened hollow hemisphere. In practice, because the wiring board 10 has the multiple bumps 14 formed in correspondence to multiple pads 18A of an IC chip 18 (FIG. 3), as many holes 15A as the number of the bumps 14 are formed in the copper foil 15.

Next, electroplating is performed while feeding the copper foil 15 with electricity, so that the gold layer 14C and the nickel layer 14B are successively formed as illustrated in FIG. 2C. The gold layer 14C and the nickel layer 14B serve as a protection layer that protects the copper layer 14A to be later formed. Further, the gold layer 14C and the nickel layer 14B also serve as a surface treatment layer for achieving good joining of solder 17 (FIG. 3) and the bump 14 that are to be later connected.

Further, after forming the gold layer 14C and the nickel layer 14B, the copper layer 14A is formed on the nickel layer 14B by electroplating. By the process so far, the bump 14 that includes the copper layer 14A, the nickel layer 14B, and the gold layer 14C is completed.

The shape of the bump 14 thus completed corresponds to the shape of the hole 15A. That is, the bump 14 has a convex shape curved like a substantially hemispherical surface. In other words, the bump 14 is circular in a plan view and has a shape like a thinly flattened hemisphere.

After the formation of the bump 14, the resist 16 is removed and the insulating layer 11 is thereafter bonded onto the bump 14 and the copper foil 15. Then, a via hole is foamed in part of the insulating layer 11 that is positioned on the bump 14, and the via 13 is formed inside the via hole. As a result, one end (the upper end in FIG. 1) of the via 13 is connected to the bump 14. The via 13 may be formed by, for example, a semi-additive process, in which a plating layer is formed by electroplating on a plating layer formed by electroless plating.

The wiring layer 12 is formed to be continuous with the via 13, and the copper foil 15 is removed, so that the wiring board 10 illustrated in FIG. 1 is completed.

As illustrated in FIG. 3, the pad 18A of the IC chip 18 is connected through the solder 17 to the bump 14 of the wiring board 10 thus manufactured. Further, the space around the solder 17 is filled with underfill resin 19 for sealing between the wiring board 10 and the IC chip 18.

Thus, an IC package 20 is completed where the IC chip 18 is mounted on the wiring board 10 of the comparative example by flip chip.

The height of the bump 14 is determined by the depth of the hole 15A formed in the copper foil 15. The holes 15A may vary in depth because of variations in the etching rate of the etching process.

Therefore, the bumps 14 may vary in height.

For this reason, in the case of connecting the pads 18A of the IC chip 18 to the bumps 14 of the wiring board 10 through the solder 17, there may be some combinations of the bumps 14 and the pads 18A where a good connection may not be obtained.

Such a poor connection between the bump 14 of the wiring board 10 and the pad 18A of the IC chip 18 may be caused by the bump 14 and the pad 18A not being connected through the solder 17 because of variations in bump height.

Such a poor connection between the bump 14 of the wiring board 10 and the pad 18A of the IC chip 18 may impair the reliability of the wiring board 10 and the IC package 20.

That is, the wiring board 10 and the IC package 20 of the comparative example have the problem of a possible decrease in reliability.

Thus, according to an aspect of the invention, a wiring board and a mounting structure are provided that may solve one or more of the above-described problems, and a method of manufacturing such a wiring board is provided.

### Embodiments

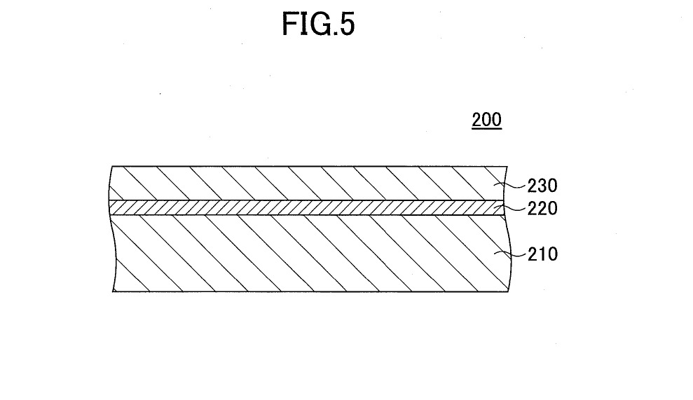

FIG. 4 is a cross-sectional view of part of a wiring board according to an embodiment. In the following description, the same elements as those of the wiring board 10 of the comparative example are referred to by the same reference numerals, and their description is omitted, or the description of the wiring board 10 is referred to for their description.

Referring to FIG. 4, a wiring board 100 according to an embodiment includes the insulating layer 11, the wiring layer 12, the via 13, and a bump 114 (a connecting part).

The insulating layer 11 is, for example, one of multiple insulating layers included in a build-up board, which is used as an interlayer insulating film between multiple wiring layers included in the build-up board.

Examples of the insulating layer 11 include an insulating layer of an epoxy resin. Further, an epoxy resin containing a filler such as alumina or silica may also be used for the insulating layer 11.

Further, prepreg may also be used for the insulating layer 11 in place of an epoxy resin. Examples of prepreg include so-called B-Stage (semi-cured) prepreg. Prepreg is, for example, a woven or nonwoven fabric of glass fibers or carbon fibers impregnated with an insulating resin such as epoxy or polyimide. A thermosetting resin is suitable as the insulating resin.

The wiring layer 12 is, for example, one of wiring layers included in a build-up board. For example, the wiring layer 12 may be formed to be continuous with the via 13. The wiring layer 12 may be formed by, for example, forming a seed layer by electroless plating and thereafter forming a copper plating film on the seed layer by electroplating according to a semi-additive process. A description is given below of a method of manufacturing the wiring layer 12.

The wiring layer 12 is patterned as desired and is connected to the via 13 formed in the insulating layer 11 in its thickness direction.

The via 13 is, for example, a via included in a build-up board and is formed inside a via hole (through hole) formed through the insulating layer 11 in its thickness direction. The via 13 may be formed to be continuous with the wiring layer 12 by a semi-additive process, for example. A description is given below of a method of manufacturing the via 13.

The via 13 has a lower end connected to the wiring layer 12 and has an upper end connected to the bump 114.

The bump 114 is connected to the upper end of the via 13 on a surface of the insulating layer 11. The bump 114 includes a copper layer 114A, a nickel layer 114B, and a gold layer 114C. The copper layer 114A, the nickel layer 114B, and the gold layer 114C are formed by plating.

Here, the nickel layer 114B and the gold layer 114C are an example of a first plating layer. The nickel layer 114B and the gold layer 114C protect the copper layer 114A and serve as a surface treatment layer for causing the below-described state of joining to the solder 17 to be good. Further, the copper layer 114A is an example of a second plating layer.

The bump 114 includes a flat surface 114D and a curved surface 114E.

The flat surface 114D serves as an upper surface of the bump 114 in FIG. 4 and is substantially circular in a plan view. The flat surface 114D is an upper surface of the gold layer 114C.

The curved surface 114E surrounds the periphery of the flat surface 114D in a plan view and extends continuously from the flat surface 114D to the surface of the insulating layer 11. The curved surface 114E is an annular surface that is continuous with the periphery of the flat surface 114D. As illustrated in FIG. 4, the curved surface 114E has a cross section that is curved substantially like a quadrant. The curved surface 114E is a side surface of the gold layer 114C.

Referring to FIG. 4, the flat surface 114D and the curved surface 114E serve as an exterior surface of the bump 114 on the insulating layer 11.

The nickel layer 114B is formed inside the gold layer 114C by plating after forming the gold layer 114C by plating. The gold layer 114C has a substantially uniform thickness. Therefore, an interior surface of the gold layer 114C before the formation of the nickel layer 114B is composed of a substantially flat surface and a curved surface.

Accordingly, a surface of the nickel layer 114B at the boundary (interface) with the gold layer 114C is composed of a substantially flat surface and a curved surface that are along (the interior surface of) the gold layer 114C.

Further, the copper layer 114A is formed on an interior surface of the nickel layer 114B by plating. Therefore, a surface of the copper layer 114A at the boundary (interface) with the nickel layer 114B is composed of a substantially flat surface and a curved surface that are along (the interior surface of) the nickel layer 114B.

A lower surface 114F (facing downward in FIG. 4) of the copper layer 114A is connected to the upper end (on the upper side in FIG. 4) of the via 13. The lower surface 114F of the copper layer 114A illustrated in FIG. 4 is depressed upward relative to the surface of the insulating layer 11. In this case, the depression on the lower surface 114F of the copper layer 114A is filled with the insulating layer 11.

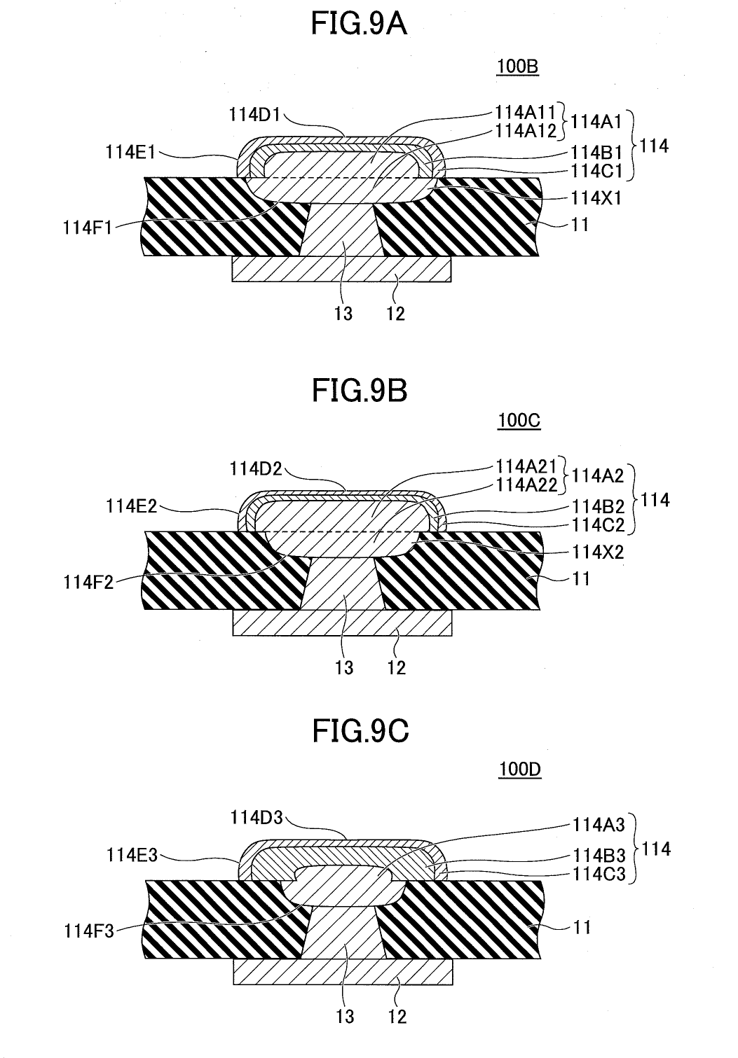

The position of the lower surface 114F of the copper layer 114A relative to the surface of the insulating layer 11 differs depending on the degree of plating performed for forming the copper layer 114A. The lower surface 114F of the copper layer 114A may be in the same plane as the surface of the insulating layer 11 or project downward relative to the surface of the insulating layer 11 in FIG. 4. See, for example, FIGS. 9A to 9C.

A description is given below of a method of manufacturing the above-described bump 114.

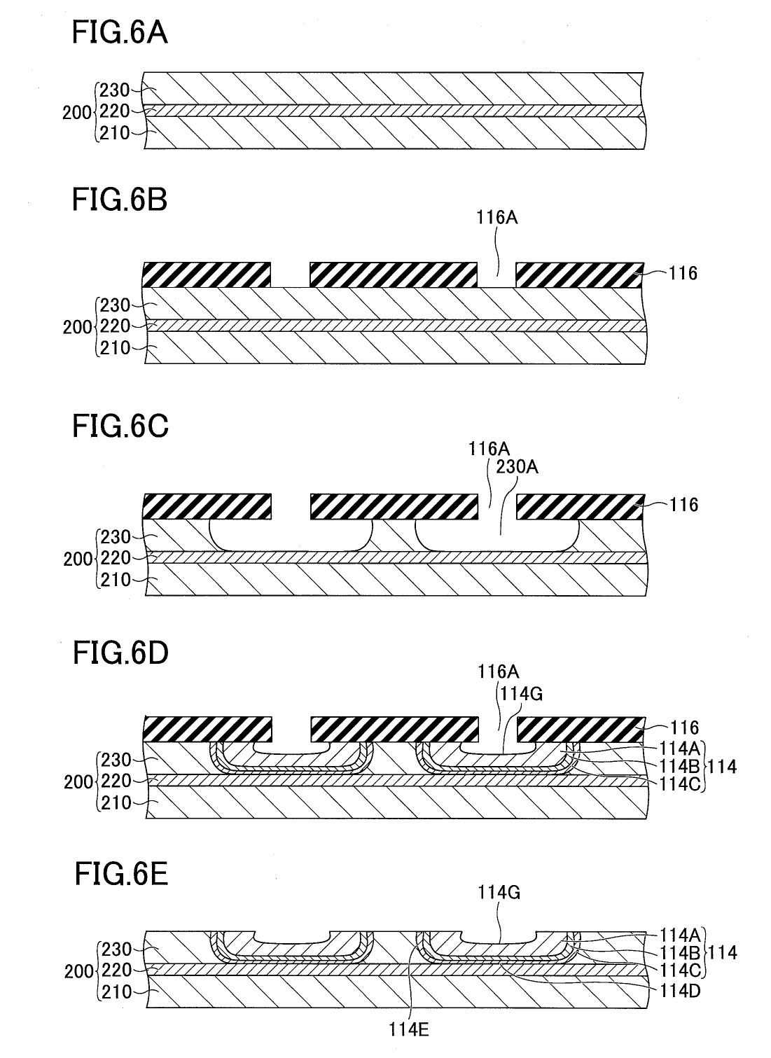

Next, a description is given, with reference to FIG. 5, of a cladding material used to manufacture the bump 114 of the wiring board 100 according to an embodiment.

FIG. 5 is a diagram illustrating a cross-sectional structure of a cladding material 200 used to manufacture the bump 114 of the wiring board 100 according to an embodiment.

The cladding material 200 includes a copper layer 210, a nickel layer 220, and a copper layer 230. The cladding material 200 is a plate-shaped member into which the copper layer 210, the nickel layer 220, and the copper layer 230 are metallurgically bonded together (joined).

Each of the copper layer 210, the nickel layer 220, and the copper layer 230 is a metal layer that has a uniform thickness and a flat surface. The flatness (evenness) of the surface of the nickel layer 220 may be such that the flatness desired as the flat surface 114D may be realized in subsequent formation of the bump 114.

The copper layer 210, which is a metal layer used as a carrier layer, is a thin plate-shaped (sheet-shaped) member that serves as a support in carrying the nickel layer 220 and the copper layer 230. The thickness of the copper layer 210 may be, for example, approximately 10 μm to approximately 100 μm.

The thickness of the copper layer 210 is not limited to this range, and may be outside this range as long as it is possible for the copper layer 210 to carry the nickel layer 220 and the copper layer 230.

The nickel layer 220 serves as an etch stop layer to stop etching in a thickness direction in selectively removing part of the copper layer 230 by wet etching. The nickel layer 220 is an example of a first metal layer.

Therefore, for wet etching of the copper layer 230, an etching solution is used that dissolves copper but not nickel. Examples of such etching solutions include alkali etching solutions.

A desired etching solution may also be suitably used as long as the etching solution selectively dissolves copper and does not dissolve nickel.

The thickness of the nickel layer 220 may be, for example, approximately 0.5 μm to approximately 10 μm. The thickness of the nickel layer 220 is not limited to this range, and may be outside this range as long as the thickness is desirable to stop etching of the copper layer 230.

The copper layer 230 is a metal layer, part of which is removed with an etching solution to form a hole. The copper layer 230 is an example of a second metal layer that is stacked on the nickel layer 220 as an example of the first metal layer.

Part of the copper layer 230 is removed by etching using the above-described etching solution, so that a hole is formed that has the surface of the nickel layer 220 at its bottom. This etching selectively removes (part of) the copper layer 230 and selectively leaves the nickel layer 220. Therefore, the surface of the nickel layer 220 serves as the bottom of the hole, so that a flat surface is obtained at the bottom of the hole. This hole is used to manufacture the bump 114 having the flat surface 114D. Electroplating for forming the bump 114 is performed while feeding the copper layer 230 with electricity.

FIG. 5 illustrates the cladding material 200 where the copper layer 210 and the copper layer 230 are different in thickness. However, the copper layer 210 and the copper layer 230 may be equal in thickness.

Further, the cladding material 200 illustrated in FIG. 5 includes the copper layer 210 that serves as a support for the nickel layer 220 and the copper layer 230. However, if the nickel layer 220 has sufficient strength to support the copper layer 230 before and after the etching, the copper layer 210 may be excluded from the cladding material 200. In this case, the cladding material 200 may be a member that has two metal layers, the nickel layer 220 as an example of the first metal layer and the copper layer 230 as an example of the second metal layer, joined to each other.

Further, for example, a metal member that has a copper layer formed by plating on a flat surface of a nickel layer may be used in place of a member formed of multiple metal layers metallurgically bonded together, such as the cladding material 200. The nickel layer of this metal member is an example of the first metal layer, and is used as an etch stop layer to stop etching of the copper layer formed by plating. The copper layer formed on one surface (flat surface) of the nickel layer by plating is an example of the second metal layer.

Further, this nickel layer may be used as a metal layer that serves as a support supporting the copper layer. Further, another metal layer may be bonded to the other surface of the nickel layer in order to ensure strength as a support.

Thus, a laminated plate including at least two metal layers, the first metal layer and the second metal layer stacked in layers, may be used to form the bump 114.

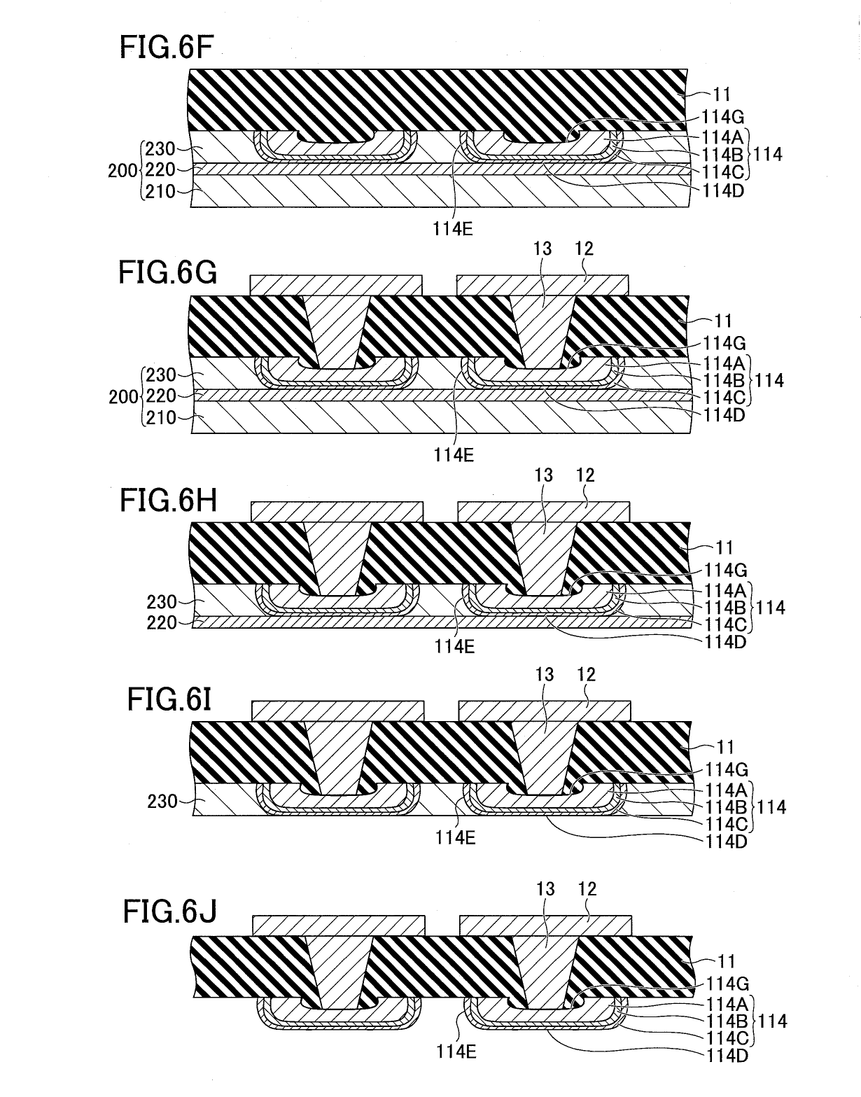

Next, a description is given, with reference to FIGS. 6A through 6J, of a method of manufacturing the wiring board 100 according to an embodiment.

FIGS. 6A through 6J are diagrams illustrating a process for manufacturing the wiring board 100 according to an embodiment.

First, as illustrated in FIG. 6A, the cladding material 200 is prepared. Here, for convenience of description, it is assumed that the copper layer 210 and the copper layer 230 are equal in thickness. At this point, the cladding material 200 is placed with the copper layer 230 facing upward.

Next, as illustrated in FIG. 6B, a resist 116 is bonded to the upper surface of the copper layer 230 of the cladding material 200. For example, a dry film may be used for the resist 116. The resist 116 is exposed to light and developed using a negative film, so that a desired pattern is formed that includes openings 116A used for later formation of the bumps 114. Each of the openings 116A is circular in a plan view.

Next, part of the copper layer 230 positioned under the openings 116A is selectively removed by ejecting an etching solution to the openings 116A using an etching apparatus, so that holes 230A are formed in the copper layer 230 as illustrated in FIG. 6C.

The etching solution used in this etching is, for example, an alkali etching solution, and dissolves copper but not nickel.

Accordingly, each of the holes 230A formed in the copper layer 230 has the flat surface of the nickel layer 220 at its bottom. Further, because of the isotropy of wet etching, the holes 230 widen laterally during their formation in a downward direction. Therefore, the width of each hole 230A decreases in a direction from the opening 116A to the nickel layer 220. As a result, each hole 230A has a side surface (sidewall surface) curved substantially like a quadrant and is circular in a plan view.

Next, the gold layer 114C, the nickel layer 114B, and the copper layer 114A are successively formed inside each hole 230A while feeding the copper layer 230 with electricity, so that the bumps 114 are formed as illustrated in FIG. 6D.

Next, the resist 116 is removed. This results in a state where the bumps 114 are embedded in part of the copper layer 230 of the cladding material 200 so as to reach the upper surface of the nickel layer 220 as illustrated in FIG. 6E. A center part 114G of each bump 114 is depressed. This depression corresponds to the depression on the lower surface 114F illustrated in FIG. 4. The resist 116 may be removed by etching using a stripping solution.

Next, as illustrated in FIG. 6F, the insulating layer 11 is formed on the bumps 114 and the upper surface of the copper layer 230 illustrated in FIG. 6E. The insulating layer 11 is also formed inside the depressions of the center parts 114G of the bumps 114. Specifically, the insulating layer 11 is formed on the respective end faces of the copper layer 114A, the nickel layer 114B, and the gold layer 114C, which are formed along a curved surface of the hole 230A, and on the upper surface of the copper layer 230 which is level with the respective end faces of the copper layer 114A, the nickel layer 114B, and the gold layer 114C.

Next, via holes are formed from the upper surface of the insulating layer 11 illustrated in FIG. 6F to reach the surfaces of the center parts 114G of the bumps 114. The vias 13 are formed inside the via holes, and the wiring layers 12 are further formed to be continuous with the via holes 13, so that a structure illustrated in FIG. 6G is obtained.

Each of the vias 13 is formed by forming a seed layer by electroless plating inside the via hole that extends from the upper surface of the insulating layer 11 to reach the surface of the bump 114, and further filling the via hole with a copper plating film by forming the copper plating film on the seed layer by electroplating.

Before forming the vias 13, a plating resist that matches the patterns of the wiring layers 12 may be formed on the insulating layer 11, and the wiring layers 12 may be formed to be continuous with the vias 13 by plating. The plating resist may be removed by etching using a stripping solution after the formation of the wiring layers 12. As a result, a structure illustrated in FIG. 6G may be obtained.

Further, by further stacking an insulating layer, vias, and wiring layers after the formation of the vias 13 and the wiring layers 12 as illustrated in FIG. 6G, a build-up board may be formed that includes the insulating layer 11.

Once a build-up board is completed, the copper layer 210 of the cladding material 200 is then removed, so that a structure is obtained where the lowermost layer is the nickel layer 220 as illustrated in FIG. 6H. For example, the copper layer 210 may be selectively removed using an alkali etching solution so as to leave the nickel layer 220.

Next, by removing the nickel layer 220, a structure is obtained where the lowermost layer is the bumps 114 and the copper layer 230 as illustrated in FIG. 6I. The nickel layer 220 may be removed by, for example, etching using a peroxide-based etching solution.

Finally, by selectively removing the copper layer 230 using, for example, an alkali etching solution, the wiring board 100 may be obtained where the bumps 114 are connected to the lower ends of the vias 13. The lower surfaces of the bumps 114 illustrated in FIG. 6J are the flat surfaces 114D (FIG. 4).

Further, the heights of the two bumps 114 illustrated in FIG. 6J are determined by the thickness of the copper layer 230. Therefore, the two bumps 114 are equal in height to each other. By thus forming the multiple bumps 114 using the cladding material 200, it is possible to equalize the heights of all the bumps 114.

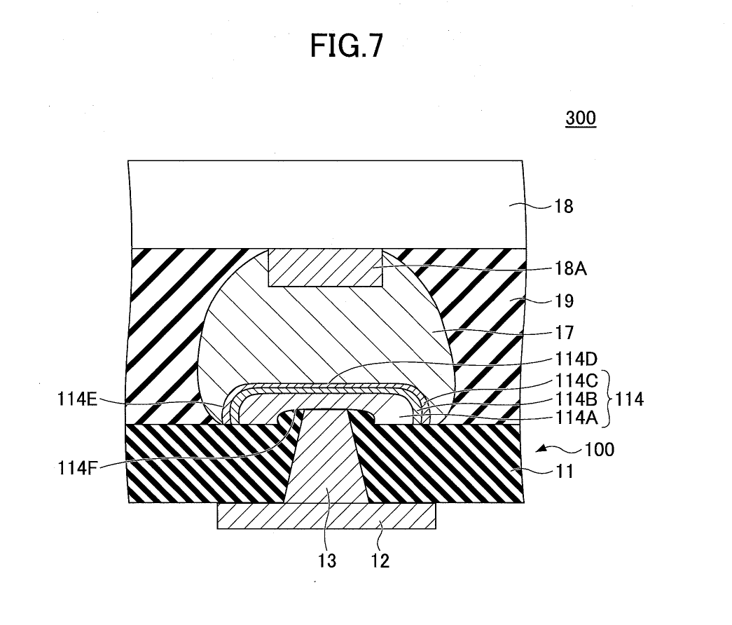

FIG. 7 is a cross-sectional view of part of an IC package 300 that includes the wiring board 100 according to an embodiment. FIG. 7 illustrates the IC package 300 where the IC chip 18 is mounted on the wiring board 100 illustrated in FIG. 4 by flip chip. The IC package 300 is an example of a mounting structure having an IC chip as an example of a semiconductor chip mounted on the wiring board 100.

Referring to FIG. 7, the IC package 300 includes the wiring board 100, the solder 17, the IC chip 18, and the underfill resin 19.

The flat surface 114D and the curved surface 114E of the bump 114 of the wiring board 100 are connected to the pad 18A of the IC chip 18 through the solder 17. Further, the space around the solder 17 is filled with the underfill resin 19 for sealing between the wiring board 100 and the IC chip 18.

Thus, the upper surface of the bump 114 of the wiring board 100 illustrated in FIG. 7 is the flat surface 114D, so that the bump 114 hardly varies in height. The multiple bumps 114, which are actually provided, are manufactured using the cladding material 200 so as to have the same height.

This is because the heights of the bumps 114 are determined by the thickness of the copper layer 230 since the etching for forming the holes 230A in the copper layer 230 (FIG. 6C) is stopped by the nickel layer 220.

Therefore, it is possible to reliably connect the plurality of bumps 114 of the wiring board 100 and the plurality of pads 18A of the IC chip 18 by the solder 17, so that it is possible to effectively prevent the occurrence of poor connections.

Because the heights of the plurality of bumps 114 are thus equalized and hardly vary, it is possible to reliably connect the plurality of bumps 114 arranged in a plane and the multiple pads 18A of the IC chip 18 by the solder 17.

Thus, according to embodiments, it is possible to provide the highly reliable wiring board 100 and IC package 300 and a method of manufacturing the wiring board 100.

Further, in the wiring board 10 of the comparative example illustrated in FIG. 1, the height of the bump 14 is not constant, and the bump 14 is highest in the plan-view center and becomes lower toward its edge. That is, the bump 14 varies in height depending on a position.

Therefore, in the wiring board 10 of the comparative example, if the planar positions of the pad 18A of the IC chip 18 and the bump 14 of the wiring board 10 are offset relative to each other, the pad 18A and the bump 14 may be prevented from being connected by the solder 17. That is, the occurrence of an offset between the planar positions of the center of the bump 14 and the center of the pad 18A may prevent the pad 18A and the bump 14 from being connected by the solder 17.

Meanwhile, the upper surface of each bump 114 of the wiring board 100 according to an embodiment is the flat surface 114D, so that the bump 114 hardly varies in height.

Therefore, even when the planar positions of the pad 18A of the IC chip 18 and the bump 114 of the wiring board 100 are offset relative to each other, it is still possible to reliably connect the pad 18A and the bump 114 by the solder 17.

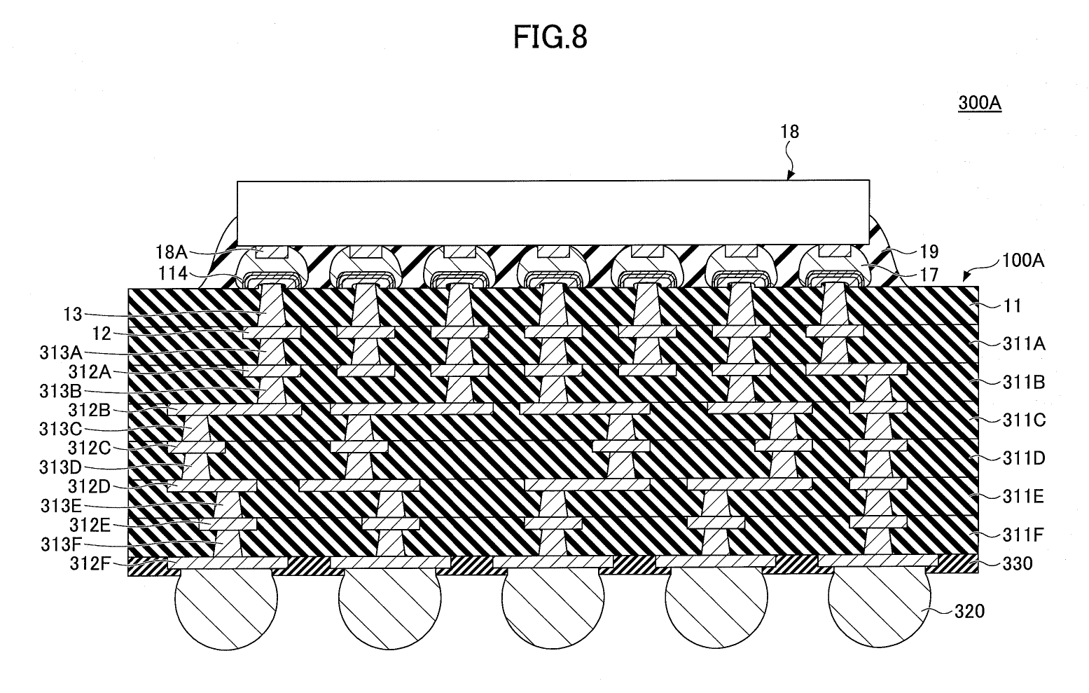

Next, a description is given, with reference to FIG. 8, of an IC package 300A that is closer to an actual state.

FIG. 8 is a cross-sectional view of the IC package 300A according to an embodiment.

FIG. 8 illustrates a wiring board 100A that includes a larger number of the bumps 114 and the IC chip 18 that includes a larger number of the pads 18A. The wiring board 100A illustrated in FIG. 8 is a build-up board that includes plural wiring layers, plural vias, and plural insulating layers, all of which are stacked on the insulating layer 11.

The wiring board 100A includes the insulating layer 11, insulating layers 311A, 311B, 311C, 311D, 311E, and 311F, the wiring layers 12, and wiring layers 312A, 312B, 312C, 312D, 312E, and 312F. The wiring board 100A further includes the vias 13, vias 313A, 313B, 313C, 313D, 313E, and 313F, and the bumps 114. The wiring layers 312F are used as pads.

FIG. 8 illustrates the seven bumps 114. The seven bumps 114 are connected to the seven pads 18A of the IC chip 18 through the solder 17.

Further, the vias 13 and the vias 313A to 313F are formed in the insulating layer 11 and the insulating layers 311A to 311F, respectively, of the wiring board 100A. The lower ends of the vias 13 and the vias 313A to 313F are connected to the wiring layers 12 and the wiring layers 312A to 312F, respectively. The upper ends of the vias 13 and the vias 313A to 313F are connected to the bumps 114 and the wiring layers 12 and the wiring layers 312A to 312E, respectively.

The wiring board 100A is manufactured, in a state upside down relative to the state illustrated in FIG. 8 (that is, with the insulating layer 11 positioned on the lower side), by stacking the insulating layers 311A to 311F on the insulating layer 11 while forming the vias 313A to 313F and the wiring layers 312A to 312F. The insulating layer 11 and the insulating layers 311A to 311F are joined by, for example, thermocompression bonding using a vacuum laminator or the like.

Further, solder bumps 320 are connected to the wiring layers 312F used as pads. Further, a lower surface of the insulating layer 311F and parts of the lower surfaces of the wiring layers 312F, which parts are not covered with the bumps 320, are covered with a solder resist 330.

The pads 18A of the IC chip 18 are connected to the bumps 114 of the wiring board 100A as described above through the solder 17 and the space between the wiring board 100A and the IC chip 18 is filled with the underfill resin 19 for sealing, so that the IC package 300A is completed.

In the IC package 300A illustrated in FIG. 8, the upper surfaces of the bumps 114 of the wiring board 100A are the flat surfaces 114D, and the bumps 114 are formed using the cladding material 200 so as to have the same height.

Therefore, according to an embodiment, it is possible to reliably connect the bumps 114 of the wiring board 100A and the pads 18A of the IC chip 18 by the solder 17, so that it is possible to effectively prevent the occurrence of poor connections.

Thus, according to embodiments, it is possible to provide the highly reliable wiring boards 100 and 100A and IC packages 300 and 300A, a method of manufacturing the wiring board 100, and a method of manufacturing the wiring board 100A.

FIG. 4 illustrates a form of the bump 114 where the lower surface 114F of the copper layer 114A is depressed upward relative to the surface of the insulating layer 11. Alternatively, the lower surface 114F of the copper layer 114A of the bump 114 may be in the same plane as the surface of the insulating layer 11 or project downward relative to the surface of the insulating layer 11 in FIG. 4.

FIGS. 9A through 9C are diagrams illustrating variations of the wiring board 100 according to an embodiment.

According to a wiring board 100B illustrated in FIG. 9A, the bump 114 includes a copper layer 114A1, a nickel layer 114B1, and a gold layer 114C1. The bump 114 of the wiring board 100B includes a flat surface 114D1, a curved surface 114E1, and a lower surface 114F1 of the copper layer 114A1. The flat surface 114D1 and the curved surface 114E1 are equal in shape and size to the flat surface 114D and the curved surface 114E, respectively, illustrated in FIG. 4.

The nickel layer 114B1 and the gold layer 114C1 are equal to the nickel layer 114B and the gold layer 114C, respectively, illustrated in FIG. 4, while the lower surface 114F1 of the copper layer 114A1 projects downward (toward the side on which the via 13 and the wiring layer 12 are formed) relative to the surface of the insulating layer 11. That is, the copper layer 114A1 includes a base part 114A11 coated with the nickel layer 114B1 and the gold layer 114C1 and a projecting part 114A12 that projects toward the lower surface 114F1 side relative to the base part 114A11. In other words, the copper layer 114A1 includes the base part 114A11 and the projecting part 114A12 that projects from (relative to) the surface of the insulating layer 11 so as to be embedded in the insulating layer 11.

Of the copper layer 114A1, a part above a broken line illustrated in FIG. 9A (the position of the surface of the insulating layer 11) is the base part 114A11 (a first portion) and a part below the broken line is the projecting part 114A12 (a second portion).

An outer edge portion 114X1 of the projecting part 114A12 is positioned more outside than the base part 114A11. This copper layer 114A1 may be obtained by, for example, suitably changing the opening 116A of the resist 116 (FIG. 6B) so that a thicker plating layer is formed in a plating process than for the copper layer 114A illustrated in FIG. 4. In the case of thus forming thick the copper layer 114A1, it is possible to reduce the lengths of the vias 13, so that it is possible to reduce electric power and a processing time for a laser process for forming via holes for forming the vias 13.

According to a wiring board 100C illustrated in FIG. 9B, the bump 114 includes a copper layer 114A2, a nickel layer 114B2, and a gold layer 114C2. The bump 114 of the wiring board 100C includes a flat surface 114D2, a curved surface 114E2, and a lower surface 114F2 of the copper layer 114A2. The flat surface 114D2 and the curved surface 114E2 are equal in shape and size to the flat surface 114D and the curved surface 114E, respectively, illustrated in FIG. 4.

The lower surface 114F2 of the copper layer 114A2 projects downward (toward the side on which the via 13 and the wiring layer 12 are formed) relative to the surface of the insulating layer 11. That is, the copper layer 114A2 includes a base part 114A21 coated with the nickel layer 114B2 and the gold layer 114C2 and a projecting part 114A22 that projects toward the lower surface 114F2 side relative to the base part 114A21.

Of the copper layer 114A2, a part above a broken line illustrated in FIG. 9B (the position of the surface of the insulating layer 11) is the base part 114A21 and a part below the broken line is the projecting part 114A22.

An outer edge portion 114X2 of the projecting part 114A22 is positioned more inside than the base part 114A21.

The projecting part 114A22 illustrated in FIG. 9B is generated when the copper layer 114A is formed to be thicker in the process illustrated in FIG. 6D. According to the wiring board 100C illustrated in FIG. 9B, as well as the wiring board 100B illustrated in FIG. 9A, it is possible to reduce electric power and a processing time for a laser process for forming via holes for forming the vias 13.

According to a wiring board 100D illustrated in FIG. 9C, the bump 114 includes a copper layer 114A3, a nickel layer 114B3, and a gold layer 114C3. The bump 114 of the wiring board 100D includes a flat surface 114D3, a curved surface 114E3, and a lower surface 114F3 of the copper layer 114A3. The flat surface 114D3 and the curved surface 114E3 are equal in shape and size to the flat surface 114D and the curved surface 114E, respectively, illustrated in FIG. 4.

According to the bump 114 of the wiring board 100D, a thicker plating layer is formed in a plating process for the nickel layer 114B3 than for the nickel layer 114B illustrated in FIG. 4. Further, the copper layer 114A3 has a shape that is obtained by ending a plating process earlier than for the copper layer 114A1 of the bump 114 illustrated in FIG. 9A. That is, the lower surface 114F3 of the copper layer 114A3 projects downward relative to the surface of the insulating layer 11, but to a lesser degree than the lower surface 114F1 of the copper layer 114A1 illustrated in FIG. 9A.

However, in the case of forming the bump 114 having the copper layer 114A3 shaped as illustrated in FIG. 9C as well, it is possible to reduce the lengths of the vias 13, so that it is possible to reduce electric power and a processing time for a laser process for forming via holes for forming the vias 13.

A description is given above of a form of the bump 114 where the bump 114 includes the copper layer 114A (the second plating layer), the nickel layer 114B, and the gold layer 114C. The nickel layer 114B and the gold layer 114C are a surface treatment layer (the first plating layer) that protects the copper layer 114A and achieves a good connection with the solder 17.

However, such a surface treatment layer is not limited to the nickel layer 114B and the gold layer 114C.

As a surface treatment layer that protects the copper layer 114A, for example, a single layer structure formed of a gold layer may be used in place of the gold layer 114C and the nickel layer 114B on the copper layer 114A. Further, a surface treatment layer of a three-layer structure composed of a nickel layer, a palladium layer, and a gold layer stacked in this order may also be used. Further, a surface treatment layer of a four-layer structure composed of a palladium layer, a nickel layer, a palladium layer, and a gold layer stacked in this order may also be used. Further, the copper layer 114A may be used alone.

Further, in place of surface treatment, an organic solderability preservative (OSP) process may be performed on the copper layer 114A.

Further, a description is given above of a form of the cladding material 200 where the cladding material 200 has a three-layer structure of the copper layer 210, the nickel layer 220, and the copper layer 230. In this case, the nickel layer 220 is an example of the first metal layer, and the copper layer 230 is an example of the second metal layer and is a metal layer whose part is removed with an etching solution to form a hole.

However, the cladding material 200 may use metal layers other than the nickel layer 220 and the copper layer 230 as the first metal layer and the second metal layer. As long as the cladding material 200 is a plate-shaped member having the first metal layer and the second metal layer metallurgically bonded together, and allows a hole to be formed by selectively removing (part of) the second metal layer by etching so as to have the flat surface of the first metal layer at its bottom, the cladding material 200 is not limited to the combination of the nickel layer 220 and the copper layer 230, and may use other metal layers. For example, the nickel layer 220 may be replaced with a tin layer.

As described above, a metal member that has a copper layer formed by plating on a flat surface of a nickel layer may be used in place of a member formed of multiple metal layers metallurgically bonded together, such as the cladding material 200.

Various aspects of the subject-matter described herein may be set out non-exhaustively in the following numbered clauses:

1. A method of manufacturing a wiring board, including:

preparing a laminated plate that includes a first metal layer and a second metal layer stacked on a flat surface of the first metal layer;

forming a hole in the laminated plate by removing a part of the second metal layer so that the flat surface of the first metal layer is exposed at a bottom of the hole;

forming a first plating layer on the flat surface exposed at the bottom of the hole and on a sidewall surface of the hole continuous with the flat surface;

forming a second plating layer on the first plating layer in the hole;

forming an insulating layer on the first plating layer, the second plating layer, and the second metal layer;

forming a via hole in the insulating layer to expose a surface of the second plating layer; and

forming a via in the through hole so that the via is connected to the surface of the second plating layer.

2. The method of manufacturing a wiring board of clause 1, wherein forming the hole in the laminated plate forms the hole by removing the part of the second metal layer by wet etching without dissolving the first metal layer.

3. The method of manufacturing a wiring board of clause 1, wherein forming the hole in the laminated plate forms the hole so that the sidewall surface of the hole is curved.

4. The method of manufacturing a wiring board of clause 1, wherein the laminated plate is a cladding material including the first metal layer and the second metal layer that are bonded together.

5. The method of manufacturing a wiring board of clause 1, wherein forming the second plating layer forms the second plating layer so that the second plating layer fills in the entire hole and projects from the hole.

6. The method of manufacturing a wiring board of clause 1, wherein forming the first plating layer and forming the second plating layer form the first plating layer and the second plating layer, respectively, by electroplating.

All examples and conditional language provided herein are intended for pedagogical purposes of aiding the reader in understanding the invention and the concepts contributed by the inventors to further the art, and are not to be construed as limitations to such specifically recited examples and conditions, nor does the organization of such examples in the specification relate to a showing of the superiority or inferiority of the invention. Although one or more embodiments of the present invention have been described in detail, it should be understood that the various changes, substitutions, and alterations could be made hereto without departing from the spirit and scope of the invention.

What is claimed is:

1. A wiring board, comprising:
an insulating layer;
a connection part provided on a surface of the insulating layer, the connection part including
a first plating layer including a flat surface and a curved surface continuous with the flat surface, wherein the flat surface and the curved surface are exposed on the insulating layer, and an end portion of the curved surface is in contact with the surface of the insulating layer; and
a second plating layer formed on an interior surface of the first plating layer so as to be coated with the first plating layer; and
a via formed in the insulating layer so as to be connected to the second plating layer.

2. The wiring board as claimed in claim 1, wherein the second plating layer includes
a first portion on a first side relative to the surface of the insulating layer, the first portion being coated with the first plating layer; and
a second portion on a second side opposite to the first side relative to the surface of the insulating layer, the second portion projecting from the surface of the insulating layer so as to be embedded in the insulating layer.

3. The wiring board as claimed in claim 2, wherein an outer edge part of the second portion is positioned more outside than the first portion.

4. The wiring board as claimed in claim 2, wherein an outer edge part of the second portion is positioned more inside than the first portion.

5. The wiring board as claimed in claim 1, wherein the first plating layer includes a plurality of plating layers.

6. A mounting structure, comprising:
the wiring board as set forth in claim 1; and
a semiconductor chip mounted on the wiring board, the semiconductor chip including a pad connected through solder to the flat surface and the curved surface of the first plating layer of the wiring board.
